(19) United States
(12) Patent Application Publication
(10) Pub. No.: US 2005/0227389 A1
(43) Pub. Date: Oct. 13, 2005

(54) Deformable organic devices

(76) Inventors: Rabin Bhattacharya, Plainsboro, NJ (US); Sigurd Wagner, Princeton, NJ (US)

Correspondence Address: KENYON & KENYON, 1500 K STREET NW, SUITE 700, WASHINGTON, DC, 20005, US

(21) Appl. No.: 10/822,789

(22) Filed: Apr. 13, 2004

(51) Int. Cl. H01L 21/00

(52) U.S. Cl. 438/22

(57) ABSTRACT

A device is provided. The device includes a substrate, an inorganic layer disposed over the substrate, and an organic layer disposed on the inorganic conductive or semiconductive layer, such that the organic layer is in direct physical contact with the inorganic conductive or semiconductive layer. The substrate is deformed such that there is a nominal radial or biaxial strain of at least 0.05% relative to a flat substrate at an interface between the inorganic layer and the organic layer. The nominal radial or biaxial strain may be higher, for example 1.5%. A method of making the device is also provided, such that the substrate is deformed after the inorganic layer and the organic layer are deposited onto the substrate.

### FIELD OF THE INVENTION

The present invention relates to organic devices, and more specifically to such devices that may be readily deformed into arbitrary shapes without reducing device yield or creating reliability issues.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic devices include organic light emitting devices (OLEDs), organic transistors, organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be an fluorescent or phosphorescent small molecule emitter. A dendrimer may be a “small molecule,” and it is believed that all dendrimers currently used in the field of OLEDs are small molecules.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

OLED devices are generally (but not always) intended to emit light through at least one of the electrodes, and one or more transparent electrodes may be useful in an organic opto-electronic devices. For example, a transparent electrode material, such as indium tin oxide (ITO), may be used as the bottom electrode. A transparent top electrode, such as disclosed in U.S. Pat. Nos. 5,703,436 and 5,707,745, which are incorporated by reference in their entireties, may also be used. For a device intended to emit light only through the bottom electrode, the top electrode does not need to be transparent, and may be comprised of a thick and reflective metal layer having a high electrical conductivity. Similarly, for a device intended to emit light only through the top electrode, the bottom electrode may be opaque and/or reflective. Where an electrode does not need to be transparent, using a thicker layer may provide better conductivity, and using a reflective electrode may increase the amount of light emitted through the other electrode, by reflecting light back towards the transparent electrode. Fully transparent devices may also be fabricated, where both electrodes are transparent. Side emitting OLEDs may also be fabricated, and one or both electrodes may be opaque or reflective in such devices.

Optoelectronic devices rely on the optical and electronic properties of materials to either produce or detect electromagnetic radiation electronically or to generate electricity from ambient electromagnetic radiation. Photosensitive optoelectronic devices convert electromagnetic radiation into electricity. Photovoltaic (PV) devices or solar cells, which are a type of photosensitive optoelectronic device, are specifically used to generate electrical power. PV devices, which may generate electrical power from light sources other than sunlight, are used to drive power consuming loads to provide, for example, lighting, heating, or to operate electronic equipment such as computers or remote monitoring or communications equipment. These power generation applications also often involve the charging of batteries or other energy storage devices so that equipment operation may continue when direct illumination from the sun or other ambient light sources is not available. As used herein the term “resistive load” refers to any power consuming or storing device, equipment or system. Another type of photosensitive optoelectronic device is a photoconductor cell. In this function, signal detection circuitry monitors the resistance of the device to detect changes due to the absorption of light. Another type of photosensitive optoelectronic device is a photodetector. In operation a photodetector has a voltage applied and a current detecting circuit measures the current generated when the photodetector is exposed to electromagnetic radiation. A detecting circuit as described herein is capable of providing a bias voltage to a photodetector and measuring the electronic response of the photodetector to ambient electromagnetic radiation. These three classes of photosensitive optoelectronic devices may be characterized according to whether a rectifying junction as defined below is present and also according to whether the device is operated with an external applied voltage, also known as a bias or bias voltage. A photoconductor cell does not have a rectifying junction and is normally operated with a bias. A PV device has at least one rectifying junction and is operated with no external bias. A photodetector has at least one rectifying junction and is usually but not always operated with a bias.

Traditionally, photosensitive optoelectronic devices have been constructed of a number of inorganic semiconductors, e.g., crystalline, polycrystalline and amorphous silicon, gallium arsenide, cadmium telluride and others. Herein the term “semiconductor” denotes materials which can conduct electricity when charge carriers are induced by thermal or electromagnetic excitation. The term “photoconductive” generally relates to the process in which electromagnetic radiant energy is absorbed and thereby converted to excitation energy of electric charge carriers so that the carriers can conduct, i.e., transport, electric charge in a material. The terms “photoconductor” and “photoconductive material” are used herein to refer to semiconductor materials which are chosen for their property of absorbing electromagnetic radiation to generate electric charge carriers.

As used herein, the term “device” is intended to be construed broadly enough to encompass structure such as interconnects that connect other devices to each other.

As used herein, “top” means furthest away from the substrate, while “bottom” means closest to the substrate. For example, for a device having two electrodes, the bottom electrode is the electrode closest to the substrate, and is generally the first electrode fabricated. The bottom electrode has two surfaces, a bottom surface closest to the substrate, and a top surface further away from the substrate. Where a first layer is described as “disposed over” a second layer, the first layer is disposed further away from substrate. There may be other layers between the first and second layer, unless it is specified that the first layer is “in physical contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

### SUMMARY OF THE INVENTION

A device is provided. The device includes a substrate, an inorganic layer disposed over the substrate, and an organic layer disposed on the inorganic conductive or semiconductive layer, such that the organic layer is in direct physical contact with the inorganic conductive or semiconductive layer. The substrate is deformed such that there is a nominal radial or biaxial strain of at least 0.05% relative to a flat substrate at an interface between the inorganic layer and the organic layer. The nominal radial or biaxial strain may be higher, for example 1.5%. A method of making the device is also provided, such that the substrate is deformed after the inorganic layer and the organic layer are deposited onto the substrate.

### BRIEF DESCRIPTION OF THE DRAWINGS

FIG. 1 shows a mechanism by which cracking may be suppressed by an organic layer.

FIG. 2 shows an organic light emitting device having separate electron transport, hole transport, and emissive layers, as well as other layers.

FIG. 3 shows an organic device on a flat substrate.

FIG. 4 shows the organic device of FIG. 3, after the substrate has been deformed.

FIG. 5 shows a top view of several devices connected by interconnects.

### DETAILED DESCRIPTION

The applications of traditional large-area electronics, such as displays, are limited by the fact that glass substrates are rigid and easily breakable. Large-area electronics, such as electronic paper, sensor skin, and electrotextiles, requires building electronic devices on flexible and deformable substrates. Substrates, such as organic polymers and stainless-steel foils, can be deformed into arbitrary shapes, but inorganic semiconductor device materials, such as amorphous silicon and silicon nitride, are brittle and crack easily when substrates are deformed. Similarly, inorganic materials typically used as conductors may also be brittle and crack relatively easily. In general, most inorganic materials are more brittle and crack more easily that organic materials, at least in the context of materials commonly used to fabricate organic electronic devices. Brittleness may be of particular concern for transparent electrodes, where the material selection is extremely limited due to the need to combine transparency and conductivity in a single material. ITO is a preferred transparent conductive inorganic material, but it has a Young's modulus of 116 GPa and a yield strength of only 1.2 GPa. Some insulative materials that may be desirable in certain types of organic devices such as thin film transistors may have fracture strains as low as 0.05% (MgO, for example). It is believed that most practical applications of embodiments of the invention will involve higher radial or biaxial strains, such as 1.5% and above. To achieve flexible electronics, it is desirable to mitigate the effects of the applied mechanical strain in such device structure on deformable substrates.

Most of the work to date has focused on cylindrical bending deformation of thin foil substrates. In such cases, the semiconductor films on the inside of the deformed surface are in compression and those on the outside are in tension, while there exists a plane between these two with no strain (neutral plane). Assuming the film thickness is negligible and the neutral plane is at the midsurface of the substrate, the magnitude of strain in the surfaces is given by:

$${ɛ}_{unilateral} = \frac{t}{2 p}$$

where t is the substrate thickness and p is the radius of curvature. Since the surface strain can be decreased by reducing the substrate thickness, tight radii of curvature can be achieved simply by using thinner substrates.

However, there are a wide variety of non-cylindrical shapes into which it may be desirable to deform a substrate having devices fabricated thereon. The permanent deformation of thin-film electronics, first fabricated by conventional methods on flat foil substrates, into a spherically shaped cap after the device fabrication process, is desirable. In contrast to rolling, with spherical deformation, the surface is in tension on both the concave and convex sides of the substrate and thinning the substrate cannot be used to reduce the strain, i.e., non-cylindrical deformation generally involves radial or biaxial strain, and substrate thinning does not eliminate radial or biaxial strain. Because inorganic semiconductor and transparent conductor materials are brittle, the uniform layers of device materials may crack during the substrate deformation. Thus, spherical deformation, or any other type of deformation that involves radial or biaxial strain, is fundamentally more difficult than cylindrical deformation because the deformation inherently involves stretching the substrate and devices on it, independent of the substrate thickness. In addition, because radial strain is essentially stretching in all directions, failure may occur at lower stress as compared to biaxial conditions, and the yield stress for uniaxial conditions may be higher than for both radial and biaxial conditions. While many embodiments of the invention are directed to suppressing the cracking of brittle materials subjected to radial or biaxial strain, due to the particular nature of radial and biaxial strain, it is believed that embodiments of the invention may also be applicable to suppressing cracking of devices subjected only to uniaxial strain, but at much higher stress levels than were previously attainable.

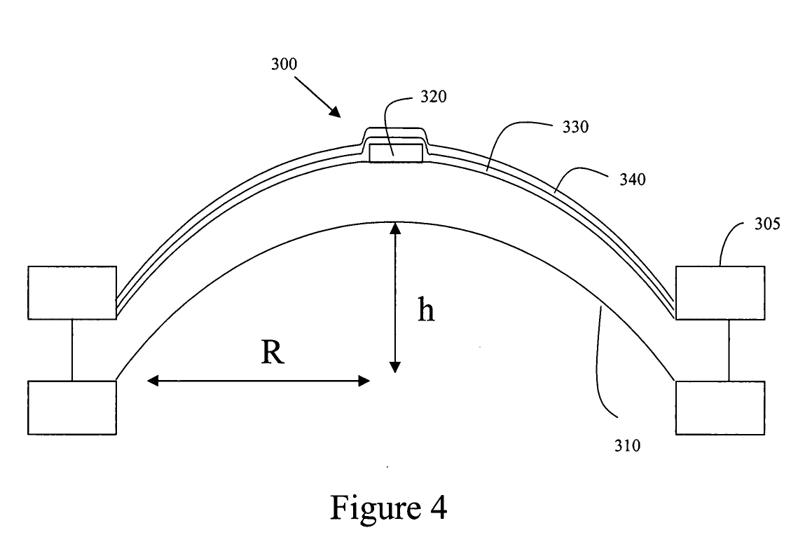

Embodiments of the invention provide a way to prevent brittle inorganic materials from cracking when deformed, even when the deformation involves radial or biaxial strain. For a flat substrate deformed into a sphere, where the initial substrate cross section is compared to the final deformed arc, the average radial strain (ε_{r,avg}) necessary to expand the foil to a spherical shape subtending a given angle (θ) is

$${ɛ}_{r , avg} = \frac{\frac{θ}{2} - sin \frac{θ}{2}}{sin \frac{θ}{2}} = \frac{{sin}^{- 1} ( \frac{2 Rh}{{R}^{2} + {h}^{2}} ) - \frac{2 Rh}{{R}^{2} + {h}^{2}}}{\frac{2 Rh}{{R}^{2} + {h}^{2}}} \approx \frac{{θ}^{2}}{24} = \frac{2}{3} {( \frac{Rh}{{R}^{2} + {h}^{2}} )}^{2} .$$

where h is the height of the spherical dome, R is the radius of the clamped substrate. R and h are illustrated in FIG. 4.

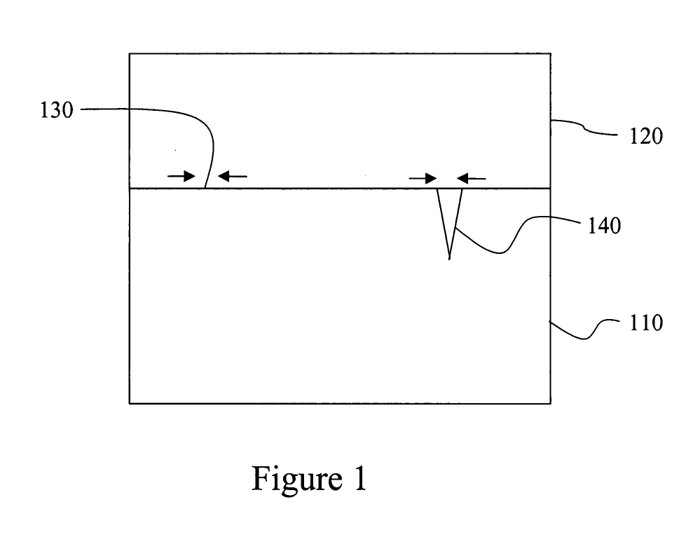

In an embodiment of the invention, an organic layer is deposited over a brittle layer, such as a layer of inorganic materials generally used in organic devices. When the device is subsequently deformed, it has been found that the brittle layer is unexpectedly much more resistant to fracture when the organic layer is present. Without intending to be limited by any theory as to how the invention works, it is believed that the organic layer may act to suppress crack formation by providing a compressive stress wherever a crack seeks to nucleate or propagate. This effect is illustrated in FIG. 1. FIG. 1 shows a brittle layer 110 having an organic layer 120 disposed thereon. Organic layer 120 is disposed over brittle layer 110, and is in direct contact with brittle layer 110. The arrows illustrate a shear compressive force applied on brittle layer 110 by organic layer 120, in directions that oppose any strain that brittle layer 110 may experience. Because organic layer 120 is organic, it may be extremely resistant to fracture, perhaps because it plastically deforms more readily than brittle layer 110. The shear compressive force may suppress crack nucleation, as indicated at point 130. Or, the shear compressive force may suppress a crack that has nucleated and is seeking to propagate, as illustrated with respect to crack 140. An alternate non-limiting theory of how the invention may work, that may or may not be cumulative with the theory illustrated in FIG. 1, is that the organic layer may provide extra stiffness to the structure, thereby absorbing some of the stress applied to the brittle layer. These theories of the invention are non-limiting, and embodiments of the invention may work for unrelated reasons.

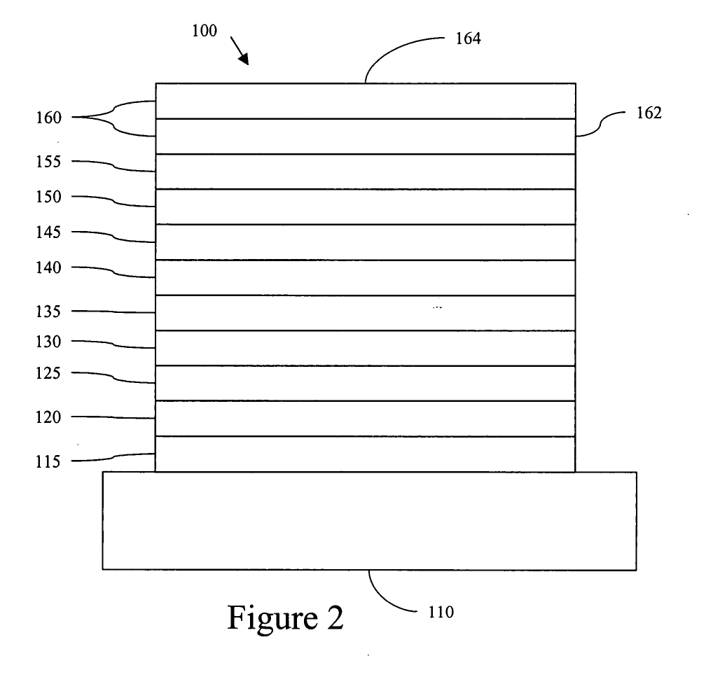

Embodiments of the present invention may involve a wide variety of organic layers that are used in a wide variety of organic devices. The organic “layer” of a particular embodiment may further comprise several organic sublayers. For example, an organic light emitting device (OLED) comprises at least one organic layer disposed between and electrically connected to an anode and a cathode, and many commerical OLEDs have a plurality of organic sublayers. For example, FIG. 2 shows an organic light emitting device 200. The figures are not necessarily drawn to scale. Device 200 may include a substrate 210, an anode 215, a hole injection layer 220, a hole transport layer 225, an electron blocking layer 230, an emissive layer 235, a hole blocking layer 240, an electron transport layer 245, an electron injection layer 250, a protective layer 255, and a cathode 260. Cathode 260 is a compound cathode having a first conductive layer 262 and a second conductive layer 264. Device 200 may be fabricated by depositing the layers described, in order. Typically, layers 220, 225, 230, 235, 240, 245, 250 and 255 each comprise organic materials, and all of these layers collectively may be considered to be an organic layer for purposes of suppressing crack formation and propagation as illustrated in FIG. 1 with respect to organic layer 130. FIG. 1 illustrates a very specific OLED configuration, and it is understood that other configuration having different layers in different orders may be used.

Embodiments of the invention may be used in connection with other improvements designed to aid in the fabrication of flexible and/or deformable organic devices. For example, the smoothness of the brittle layer may be a significant parameter, as described in U.S. Pat. No. 5,844,363, which is incorporated by reference in its entirety.

Structures and materials not specifically described may also be used, such as OLEDs comprised of polymeric materials (PLEDs) such as disclosed in U.S. Pat. No. 5,247,190, Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIG. 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. patent application Ser. No. 10/233,470, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used.

Devices fabricated in accordance with embodiments of the invention may be incorporated into a wide variety of consumer products, including flat panel displays, computer monitors, televisions, billboards, lights for interior or exterior illumination and/or signaling, heads up displays, fully transparent displays, flexible displays, laser printers, telephones, cell phones, personal digital assistants (PDAs), laptop computers, digital/cameras, camcorders, viewfinders, micro-displays, vehicles, a large area wall, theater or stadium screen, or a sign. Various control mechanisms may be used to control devices fabricated in accordance with the present invention, including passive matrix and active matrix. Many of the devices are intended for use in a temperature range comfortable to humans, such as 18 degrees C. to 30 degrees C., and more preferably at room temperature (20-25 degrees C.).

The materials and structures described herein may have applications in devices other than OLEDs. For example, other optoelectronic devices such as organic solar cells and organic photodetectors may employ the materials and structures. More generally, organic devices, such as organic transistors or memories, may employ the materials and structures.

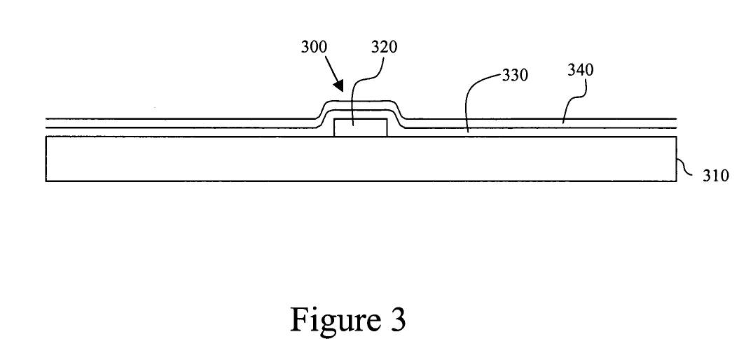

Because device fabrication may be easier on a flat substrate than on a curved substrate, it may be desirable to fabricate devices on a flat substrate, and then subsequently deform the substrate. FIGS. 3 and 4 illustrate an embodiment that provides an example of such fabrication and subsequent deformation.

In accordance with an embodiment of the invention, devices may be fabricated on one or more islands disposed on a deformable substrate. FIG. 3 illustrates one such device. Device 300 includes a deformable substrate 310, first inorganic layer 320, organic layer 330, and second inorganic layer 340. First inorganic layer comprises a rigid inorganic material, and forms an island on deformable substrate 310. Organic layer 330 is disposed over first inorganic layer 320, and is in direct contact with first inorganic layer 320. Second inorganic layer 340 is disposed over organic layer 330. In the embodiment of FIG. 3, organic layer 330 can suppress crack formation in first inorganic layer 320 when deformable substrate 310 is deformed.

With respect to the “direct contact” between an inorganic brittle layer and an organic layer, it is understood that the inorganic layer may be other than those specifically illustrated in FIGS. 1-3. For example, if there is an inorganic dielectric deposited over the interconnect to prevent shorting, an organic layer deposited over the dielectric may suppress cracking. In addition, an organic layer disposed over a barrier coated substrate may suppress cracking in the barrier.

FIG. 4 shows the device of FIG. 3, after deformable substrate 310 has been deformed. One way to deform substrate 310, which was used to generate the data of the examples, is to provide an annular clamp 305 around substrate 310, and to introduce pressurized gas behind substrate 310 to cause substrate 310 to deform.

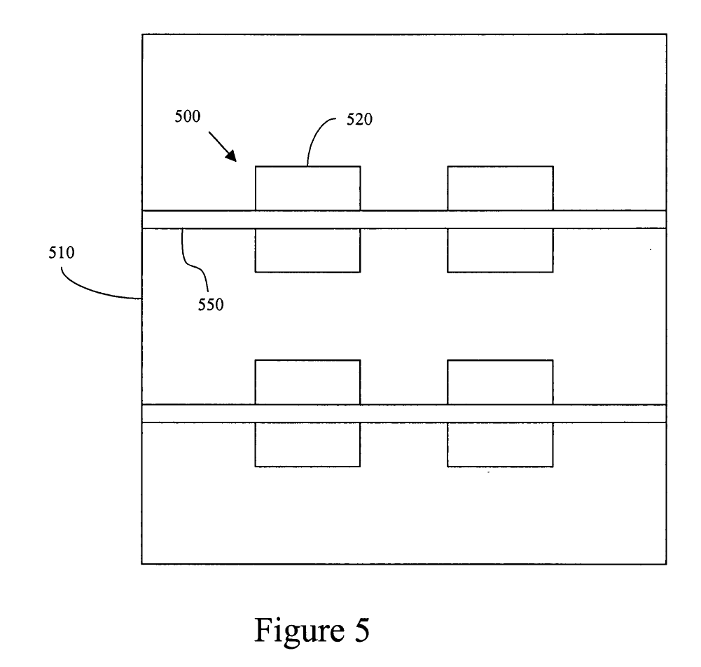

Although FIGS. 3 and 4 illustrate only a single device 300 in isolation for ease of illustration, it is understood that substrate 310 can accommodate a plurality of devices 300, and that there may be interconnects, as illustrated in FIG. 5. FIG. 5 shows four devices 500. Each device includes deformable substrate 510 and a first inorganic layer 520. Each device also includes an organic layer, and may include a second inorganic layer. These latter layers are not illustrated in FIG. 5 for ease of illustration. Devices 500 may be electrically connected to each other by interconnects 550. One order in which the parts of a device may be deposited is as follows: deposit over deformable substrate 510 a first inorganic layer 520, patterned into islands, then deposit interconnects 550, then deposit an organic layer, and then deposit a second inorganic layer.

If devices 500 are OLEDs, for example, first inorganic layer 520 may comprise indium tin oxide (ITO), which acts as a first electrode. The organic layer (see organic layer 320 of FIG. 3) may comprise a stack of organic OLED materials, such as PEDOT, CuPc, NPD, and Alq₃, deposited in that order. The second inorganic layer (see second inorganic layer 330 of FIG. 3) may comprise a layer of LiF and a layer of Al, which acts as a second electrode. Interconnects 550 and a top blanket electrode (inorganic layer 330) may be used to apply a voltage across the devices. Using various interconnect configurations, and possibly transistors (which may be organic transistors fabricated in accordance with embodiments of the invention), various active and passive matrix designs may be used to control which devices emit light. Other types of organic devices may also be fabricated, such as photosensitive optoelectronic devices, or organic transistors.

FIGS. 3-5 illustrate devices that include a first inorganic layer 320 (or 520) that is shaped into islands. Such islands may be a preferred embodiment, because islands allow any strain that occurs in deformable substrate 310 (or 510) to concentrate in the interstices between the islands, such that the deformable substrate 310 is effectively “pinned” beneath the islands, and deforms much less in the regions beneath the islands than in the interstices. On a stiff substrate, there may be significant interactions between the strain concentrations generated by neighboring islands for fill factors that are greater than 50%, so a fill factor not greater than 50% is preferred. The “fill factor” is the percentage of the area of the substrate that is covered by islands. For the geometry of FIG. 5, with square islands having sides with a length R₁ and a center to center island separation R₂, the fill factor is (R₁|R₂)². The term “nominal strain” as used herein refers to the amount of strain that would occur at the surface of a substrate where it contacts a first inorganic layer, if there were no inorganic layer present—i.e., the term “nominal strain” assumes that there is no pinning beneath the first inorganic layer, and no strain concentration in any interstices that may exist between islands of the first inorganic layer. Island structures with inorganic devices on deformable substrates are described in the literature, such as Hsu et. al, “Amorphous Si TFTs on plastically deformed spherical domes,” J. Non-Crystalline Solids 299-302 (2002). Such literature does not predict the unexpectedly good device yields and reduced susceptibility to fracture of brittle materials obtained with organic devices as opposed to inorganic devices.

It has been shown that there are significant improvements in device yields due to the presence of an organic layer, where the devices included ITO islands that were 200 nm thick, and the islands had a largest dimension of 113 microns, 141 microns, and 169 microns. It is expected that island dimension at which the presence of an organic material has a significant effect will vary with the thickness of the brittle inorganic layer, because thinner inorganic layers may be more fragile, and thus susceptible to fracture at smaller largest dimensions. The fill factor and island size at which cracking becomes an issue depends on a number of factors, including the properties of the substrate the the thickness of the islands. For example, depending upon these factor, cracking may become an issue at island sizes ranging from 1 micron to 1 mm, or even at sizes outside of this range.

Significant increases in device yield were observed where a brittle inorganic layer was covered by an organic layer that was 110 nm thick. It is expected that thicker layers would lead to even better yields. Significant decreases in interconnect cracking were observed for interconnects covered by organic layers that were 160 nm thick. Due to differences in the structure of interconnects as compared to other devices (interconnects tend to be elongated), it is believed that thicker organic layers may be needed to suppress cracking.

Although islands may be a preferred embodiment, it is expected that an organic layer disposed over an inorganic layer will suppress crack formation even in the absence of islands in the inorganic layer. A structure that does not include islands may be commercially desirable for situations where a large fill factor may be desirable, such as lighting applications involving deformable substrates.

In addition, it is expected that an organic layer disposed over an inorganic layer will suppress cracking in the inorganic layer, whether or not the inorganic layer is an electrode. For example, it was observed that interconnects covered with organic material did not crack upon deformation of the substrate, while similar interconnect that were not covered with organic material did crack upon similar deformation of the substrate.

In a preferred embodiment of the invention, the deformation of a substrate occurs above the glass transition temperature of the substrate. It is believed that deformation above the glass transition temperature allows for easier deformation of the substrate, which may to some degree relieve stress on any overlying brittle layers.

In a preferred embodiment of the invention, the substrate is deformed slowly. For example, a strain rate of 1.5% over 50 minutes may be considered slow. It is believed that slow deformation allows the substrate time to plastically deform, which may to some degree relieve stress on any overlying brittle layers.

It is understood that the various embodiments described herein are by way of example only, and are not intended to limit the scope of the invention. For example, many of the materials and structures described herein may be substituted with other materials and structures without deviating from the spirit of the invention. It is understood that various theories as to why the invention works are not intended to be limiting.

Material Definitions:

As used herein, abbreviations refer to materials as follows. With the exception of ITO, the following materials are non-limiting examples of organic materials that may be useful for embodiments of the present invention.

| | |
|---|---|
| CBP: | 4,4′-N,N-dicarbazole-biphenyl |
| m-MTDATA | 4,4′,4″-tris(3-methylphenyl- |
| | phenlyamino)triphenylamine |
| Alq₃: | 8-tris-hydroxyquinoline aluminum |
| Bphen: | 4,7-diphenyl-1,10-phenanthroline |
| n-BPhen: | n-doped BPhen (doped with lithium) |
| F₄-TCNQ: | tetrafluoro-tetracyano-quinodimethane |
| p-MTDATA: | p-doped m-MTDATA (doped with F₄-TCNQ) |
| Ir(ppy)₃: | tris(2-phenylpyridine)-iridium |
| Ir(ppz)₃: | tris(1-phenylpyrazoloto,N,C(2′)iridium(III) |
| BCP: | 2,9-dimethyl-4,7-diphenyl-1,10-phenanthroline |
| TAZ: | 3-phenyl-4-(1′-naphthyl)-5-phenyl-1,2,4-triazole |
| CuPc: | copper phthalocyanine. |
| ITO: | indium tin oxide |
| NPD: | N,N’-diphenyl-N-N’-di(1-naphthyl)-benzidine |
| TPD: | N,N’-diphenyl-N-N’-di(3-toly)-benzidine |
| BAlq: | aluminum(III)bis(2-methyl-8-hydroxyquinolinato)4- |
| | phenylphenolate |
| mCP: | 1,3-N,N-dicarbazole-benzene |
| DCM: | 4-(dicyanoethylene)-6-(4-dimethylaminostyryl-2- |
| | methyl)-4H-pyran |
| DMQA: | N,N’-dimethylquinacridone |
| PEDOT:PSS: | an aqueous dispersion of poly(3,4- |
| | ethylenedioxythiophene) with polystyrenesulfonate (PSS) |

Experimental:

Specific representative embodiments of the invention will now be described, including how such embodiments may be made. It is understood that the specific methods, materials, conditions, process parameters, apparatus and the like do not necessarily limit the scope of the invention.

Deformable substrates of polyethylene (PET), with ITO predeposited thereon in a blanket layer to a thickness of about 140-150 nm was obtained from CPFilms, Inc. of Martinsville, Va. The ITO was patterned into square islands of various sizes and with various fill factors, as described in Table 1 below. Islands with sides of 20 microns, 50 microns, 80 microns, 100 microns, and 120 microns were patterned, with fill factors of 44%, 25%, 16%, 9% and 4%. These islands may be referred to as having a “largest dimension” that is the diagonal dimension across the square, i.e., the length of the side times the square root of 2. Gold interconnects were then deposited and patterned by lift-off. The gold interconnects were 35 microns wide, and 120 m thick. An organic layer of an OLED was then deposited. The organic layer included 2 coats of PEDOT spun on at 2000 rpm for 40 seconds per coat, for a PEDOT thickness of 250 nm (PEDOT thickness based on measurements using silicon wafers). The organic layer also included 10 nm of CuPc, 50 nm NPD, and 50 nm Alq₃, blanket deposited by thermal evaporation in an e-beam system, in that order, over the PEDOT. A second inorganic layer was deposited over the organic layer. The second inorganic layer included 0.5 nm LiF and 100 nm Al, deposited in that order by thermal evaporation in an e-beam system. These devices are described below as “Sample A, with OLED.” Similar devices were fabricated for comparison purposes that did not include the organic layer or the second inorganic layer (“Sample B, without OLED”).

The substrates on which the devices were formed were deformed, in a manner similar to that illustrated in FIGS. 3 and 4. The deformation was to a nominal radial strain of 1.5% achieved over 50 minutes. The deformation was performed at 80 degrees C., which is just above the 76 degrees C. glass transition temperature of PET, but still significantly below the thin-film glass transition temperature of the organic materials in the OLED. The circular ring used to clamp the substrate during deformation had an inner diameter of of 6 cm. It is believed that, when OLED materials are in a thin film, the glass transition temperature may be higher than it is for the same materials in bulk. It is expected that the substrate strain under the islands was much reduced below the nominal strain, and that strain was concentrated in the interstices between the islands. The yields for the various island sizes and fill factors are described in Table 1. “Yield” refers to the percentage of devices that did not crack upon deformation of the substrate.

TABLE 1

| | | | | | |
|---|---|---|---|---|---|
| FF/Size | 20 μm | 50 μm | 80 μm | 100 μm | 120 μm |

Sample A (with OLED)

| | | | | | |
|---|---|---|---|---|---|
| 44% | 100% | 100% | 91% | 79% | 59% |
| 25% | 100% | 99% | 92% | 77% | 61% |
| 16% | 100% | 98% | 96% | 83% | 62% |
| 9% | 100% | 99% | 95% | 82% | 62% |
| 4% | 100% | 100% | 92% | 84% | 61% |

Sample B (without OLED)

| | | | | | |
|---|---|---|---|---|---|
| 44% | 100% | 95% | 64% | 31% | 19% |
| 25% | 100% | 98% | 73% | 42% | 20% |
| 16% | 100% | 98% | 70% | 34% | 20% |
| 9% | 100% | 98% | 64% | 36% | 12% |
| 4% | 100% | 100% | 74% | 41% | 6% |

Devices fabricated on islands with a dimension of 50 μm and 20 μm had yields near 100%, and there was no statistically significant difference in the yield of structures with the OLED and without the OLED at these sizes, showing that for small enough islands, fracture may not be an issue.

Devices similar to those described above were fabricated, but with some differences. Sample C was similar to Sample A, but had 300 nm thick aluminum interconnects instead of 120 nm thick gold interconnects. Sample C had no PEDOT. Sample D was identical to sample C, but with the Alq₃ thickness increased to 100 nm. It was observed that the aluminum interconnects cracked upon deformation in Sample C, but not in Sample D, illustrating that a thicker organic layer may have superior crack suppression properties as compared to a thinner organic layer. Sample D also had better island yields than Sample A, illustrating that a thicker organic layer may have an increased beneficial effect on island yield.

TABLE 2

| FF/Size | 20 μm | 50 μm | 80 μm | 100 μm | 120 μm |
|---|---|---|---|---|---|
| 44% | 100% | 100% | 94% | 86% | 68% |
| 25% | 100% | 100% | 99% | 80% | 70% |
| 16% | 100% | 100% | 100% | 89% | 61% |
| 9% | 100% | 100% | 100% | 86% | 80% |
| 4% | 100% | 100% | 100% | 81% | 67% |

While the present invention is described with respect to particular examples and preferred embodiments, it is understood that the present invention is not limited to these examples and embodiments. The present invention as claimed therefore includes variations from the particular examples and preferred embodiments described herein, as will be apparent to one of skill in the art.

1. A device, comprising:
a substrate;
an inorganic layer disposed over the substrate;
an organic layer disposed on the inorganic conductive or semiconductive layer, such that the organic layer is in direct physical contact with the inorganic conductive or semiconductive layer;
wherein the substrate is deformed such that there is a nominal radial or biaxial strain of at least 0.05% relative to a flat substrate at an interface between the inorganic layer and the organic layer.

2. The device of claim 1, wherein the inorganic layer forms islands.

3. The device of claim 2, wherein the islands cover at most 50% of the surface area of the substrate.

4. The device of claim 2, wherein the islands have a largest diameter of at least 70 microns.

5. The device of claim 2, wherein the islands have a largest diameter of at least 113 microns.

6. The device of claim 2, wherein the islands have a largest diameter of at least 141 microns.

7. The device of claim 2, wherein the islands have a largest diameter of at least 169 microns.

8. The device of claim 1, wherein the inorganic layer forms an island that is electrically connected to other islands by a conductive interconnect, and the organic layer is disposed over and is in direct physical contact with the interconnect.

9. The device of claim 1, wherein the inorganic layer forms an island that is electrically connected to other islands by a conductive interconnect, and there is an inorganic dielectric layer disposed over the interconnect, and the organic layer is disposed over and is in direct physical contact with the inorganic dielectric layer.

10. The device of claim 1, wherein the device is an organic light emitting device.

11. The device of claim 10, wherein the organic layer further comprises an organic electron transport layer, an organic emissive layer, and an organic hole transport layer.

12. The device of claim 1, wherein the device is a photosensitive organic device.

13. The device of claim 12, wherein the organic layer further comprises a photoactive organic layer.

14. The device of claim 12, wherein the device is a solar cell.

15. The device of claim 12, wherein the device is a photodetector.

16. The device of claim 1, wherein the device is a transistor.

17. The device of claim 1, wherein the device is a memory.

18. The device of claim 1, wherein the device is an interconnect.

19. The device of claim 1, wherein the organic layer further comprises a small molecule organic layer.

20. The device of claim 1, wherein the organic layer further comprises a polymeric organic layer.

21. The device of claim 1, wherein the organic layer has a thickness of at least 110 nm.

22. The device of claim 21, wherein the organic layer has a thickness of at least 160.

23. The device of claim 1, wherein the deformed substrate forms a section of a sphere.

24. The device of claim 2, wherein the organic layer is a blanket layer that covers both inorganic conductive or semiconductive layer that forms as island, and exposed regions of the substrate near the island.

25. The device of claim 1, wherein the substrate is a metal foil.

26. The device of claim 1, wherein the substrate is a polymer.

27. The device of claim 1, wherein the inorganic layer is conductive or semiconductive.

28. The device of claim 1, wherein the inorganic material has a Young's modulus of at least 116 GPa, and a yield strength of at most 1.2 GPa.

29. The device of claim 1, wherein the substrate is deformed such that there is a nominal radial or biaxial strain of at least 1.5% relative to a flat substrate at an interface between the inorganic layer and the organic layer.

30. A device, comprising:
a substrate;
an inorganic layer disposed over the substrate;
an organic layer disposed on the inorganic layer, such that the organic layer is in direct physical contact with the inorganic layer;
wherein the substrate is deformed such that there is a nominal axial strain of at least 5% relative to a flat substrate at an interface between the inorganic layer and the organic layer.

31. A method of fabricating a device, comprising:
depositing an inorganic conductive or semiconductive layer disposed over a substrate, the substrate having an original configuration;
depositing an organic layer on the inorganic conductive or semiconductive layer, such that the organic layer is in direct physical contact with the inorganic conductive or semiconductive layer;
deforming the substrate such that there is an average radial or biaxial strain of at least 0.05% relative to the original configuration.

32. The method of claim 31, wherein the substrate is deformed such that there is an average radial or biaxial strain of at least 1.5% relative to the original configuration

33. The method of claim 32, wherein the original configuration is a flat substrate.

34. The method of claim 31, wherein the substrate is plastically deformed.

35. The method of claim 31, wherein the substrate has a glass transition temperature, and the substrate is deformed at a temperature that exceeds its glass transition temperature.

36. The method of claim 31, wherein the substrate is deformed at a maximum strain rate of 1.5% per 50 minutes.

37. A device fabricated by the process of:
depositing an inorganic conductive or semiconductive layer disposed over a substrate, the substrate having an original configuration;
depositing an organic layer on the inorganic conductive or semiconductive layer, such that the organic layer is in direct physical contact with the inorganic conductive or semiconductive layer;
deforming the substrate such that there is an average radial or biaxial strain of at least 0.05% relative to the original configuration.
